(19) United States
(12) Patent Application Publication
(10) Pub. No.: US 2026/0106688 A1
(43) Pub. Date: Apr. 16, 2026

(54) RATE PROFILE DESIGN SYSTEM AND METHOD FOR POLARIZATION-ADJUSTED CONVOLUTIONAL CODING

(71) Applicant: Samsung Electronics Co., Ltd., Gyeonggi-do (KR)

(72) Inventors: Homayoon Hatami, San Diego, CA (US); Hamid Saber, San Diego, CA (US); Jung Hyun Bae, San Diego, CA (US)

(21) Appl. No.: 19/346,374

(22) Filed: Sep. 30, 2025

Related U.S. Application Data
(60) Provisional application No. 63/705,753, filed on Oct. 10, 2024.

(51) Int. Cl. H04L 1/00

(52) U.S. Cl. CPC H04L 1/0041; H04L 1/0057

(57) ABSTRACT

A system and method of defining a rate profile of a pre-coded polar code are disclosed. The method includes obtaining an allocation tuple that specifies, for at least one component included in a plurality of components, a count of information-bit positions equal to a message length; for the at least one component, selecting, from a catalog, an information set of a component code corresponding to the count of information-bit positions; generating a global information index set by concatenating the information set of the component code with an offset; and transmitting, via an encoder, a codeword generated using a rate-profiling module configured based on the global information index set.

### CROSS-REFERENCE TO RELATED APPLICATION

This application claims the priority benefit under 35 U.S.C. § 119(c) of U.S. Provisional Application No. 63/705,753, filed on Oct. 10, 2024, the disclosure of which is incorporated by reference in its entirety as if fully set forth herein.

### TECHNICAL FIELD

The disclosure generally relates to data communication systems. More particularly, the subject matter disclosed herein relates to error-correcting coding for wireless communication systems.

### SUMMARY

Digital communication systems, including wireless cellular networks, satellite links, Internet of Things (IoT) devices, and other data communication environments, may employ polar codes and polarization-adjusted convolutional (PAC) codes to provide forward-error correction with favorable latency and implementation characteristics. A polar or PAC code can be characterized by an information-bit set (also referred to as a rate profile) that selects which polarized bit-channels carry user data and which are fixed, and system performance (e.g., block error rate (BLER)), complexity, and robustness across channel conditions, can depend on this selection.

To improve system performance, previous solutions have used fixed design tables, density-evolution or Gaussian-approximation driven constructions, heuristic searches, or handcrafted rules that tune the information set for a particular code length, rate, and decoder (e.g., successive-cancellation list (SCL) or cyclic-redundancy-check (CRC)-aided SCL). These approaches can produce rate profile configurations that allow the code to achieve acceptable BLER performance under one or more given assumptions, but they are often tailored to a narrow operating point, require significant computation when channel assumptions change, and do not readily use runtime feedback about how a given profile behaves on actual traffic or on a particular hardware pipeline.

One issue with the above approach is that 0-1 rate assignments may leave capacity on partially reliable bit-channels unused and can be vulnerable to diverse deployment realities, such as mismatched channel models, puncturing/shortening, list-size constraints, or content-dependent statistics. In practice, a modem may need a data-driven way to adapt or select information sets that generalize across signal to noise ratios (SNRs), bandwidth parts, and decoder configurations without an exhaustive redesign for each case.

To overcome these types of issues, systems and methods are described herein for learning-based design and selection of information-bit sets for polar and PAC codes. In various embodiments, a problem is framed as a sequential decision process in which a controller (e.g., a reinforcement learning (RL) agent such as a deep Q-network) proposes information-bit indices for a code of length N, optionally decomposed into multiple component codes for tractable exploration; invalid or rate-violating actions may be masked; and a reward may be computed from one or more performance metrics (e.g., BLER, decoding latency, or energy) obtained under a target decoder (e.g., SCL, CRC-aided SCL, or other decoders). The learned profiles can be initialized from known patterns (e.g., standardized baselines), refined with replay and on/offline evaluation, and stored in a profile library indexed by code length, rate, SNR region, bandwidth part, puncturing pattern, and/or decoder parameters. Embodiments may further support PAC pre-encoding kernels, mixed objectives (e.g., BLER subject to latency or list-size constraints), and deployment either in baseband firmware/software or accelerator logic, while remaining decoder-agnostic at the interface level.

The above approaches improve on previous methods because the controller can automatically discover profiles that reduce BLER and/or complexity across a range of operating conditions, adapt to implementation constraints without per-scenario re-derivation, and exploit real performance feedback from the target stack. As a result, embodiments may provide faster acquisition of high-quality rate profiles, improved resilience to channel/model mismatch, compatibility with PAC pre-encoding, and portability across devices and applications, including cellular, satellite, and other digital systems.

According to an embodiment, a computer-implemented method of defining a rate profile of a pre-coded polar code includes obtaining an allocation tuple that specifics, for at least one component included in a plurality of components, a count of information-bit positions equal to a message length; for the at least one component, selecting, from a catalog, an information set of a component code corresponding to the count of information-bit positions; generating a global information index set by concatenating the information set of the component code with an offset; and transmitting, via an encoder, a codeword generated using a rate-profiling module configured based on the global information index set.

According to another embodiment, a computer-implemented method for designing an information index set of a pre-coded polar code includes, for a current allocation tuple, generating a global information index set by selecting, for a component included in a plurality of components, an information set from a catalog; measuring a block-error rate for a code that uses the global information index set; updating the allocation tuple by transferring one information position between components while preserving a total equal to a message length; iterating at least one of the generating, measuring, or updating to select an allocation tuple having a lowest measured block-error rate within an episode; and transmitting a codeword generated using a rate profiling module configured with the global information index set.

According to another embodiment, a non-transitory computer-readable medium storing instructions is disclosed. The instructions, when executed by one or more processors of an electronic device, cause the one or more processors to obtain an allocation tuple that specifies, for at least one component included in a plurality of components, a count of information-bit positions equal to a message length; for the at least one component, select, from a catalog, an information set of a component code corresponding to the count of information-bit positions; generate a global information index set by concatenating the information set of the component code with an offset; and transmit, via an encoder, a codeword generated using a rate-profiling module configured based on the global information index set.

### BRIEF DESCRIPTION OF THE DRAWING

In the following section, the aspects of the subject matter disclosed herein will be described with reference to exemplary embodiments illustrated in the figures, in which:

FIG. 1 illustrates a transmitting device or a receiving device in a communication system, according to an embodiment;

FIG. 2 illustrates an example encoding pipeline for PAC codes, according to an embodiment;

FIG. 3 is a flowchart illustrating a list decoding approach, according to an embodiment;

FIG. 4 illustrates an example construction of an information index set for a length-N=8, K=4 code that is partitioned into M=2 components of equal size, according to an embodiment;

FIG. 5A is a flowchart illustrating a method of defining a rate profile of a pre-coded polar code, according to an embodiment;

FIG. 5B is a flowchart illustrating a method for designing an information index set of a pre-coded polar code, according to an embodiment;

FIG. 6 is a block diagram of an electronic device in a network environment, according to an embodiment; and

FIG. 7 is a system including a user equipment (UE) and a base station, in communication with each other, according to an embodiment.

### DETAILED DESCRIPTION

In the following detailed description, numerous specific details are set forth in order to provide a thorough understanding of the disclosure. It will be understood, however, by those skilled in the art that the disclosed aspects may be practiced without these specific details. In other instances, well-known methods, procedures, components and circuits have not been described in detail to not obscure the subject matter disclosed herein.

Reference throughout this specification to “one embodiment” or “an embodiment” means that a particular feature, structure, or characteristic described in connection with the embodiment may be included in at least one embodiment disclosed herein. Thus, the appearances of the phrases “in one embodiment” or “in an embodiment” or “according to one embodiment” (or other phrases having similar import) in various places throughout this specification may not necessarily all be referring to the same embodiment. Furthermore, the particular features, structures or characteristics may be combined in any suitable manner in one or more embodiments. In this regard, as used herein, the word “exemplary” means “serving as an example, instance, or illustration.” Any embodiment described herein as “exemplary” is not to be construed as necessarily preferred or advantageous over other embodiments. Additionally, the particular features, structures, or characteristics may be combined in any suitable manner in one or more embodiments. Also, depending on the context of discussion herein, a singular term may include the corresponding plural forms and a plural term may include the corresponding singular form. Similarly, a hyphenated term (e.g., “two-dimensional,” “pre-determined,” “pixel-specific,” etc.) may be occasionally interchangeably used with a corresponding non-hyphenated version (e.g., “two dimensional,” “predetermined,” “pixel specific,” etc.), and a capitalized entry (e.g., “Counter Clock,” “Row Select,” “PIXOUT,” etc.) may be interchangeably used with a corresponding non-capitalized version (e.g., “counter clock,” “row select,” “pixout,” etc.). Such occasional interchangeable uses shall not be considered inconsistent with each other.

Also, depending on the context of discussion herein, a singular term may include the corresponding plural forms and a plural term may include the corresponding singular form. It is further noted that various figures (including component diagrams) shown and discussed herein are for illustrative purpose only, and are not drawn to scale. For example, the dimensions of some of the elements may be exaggerated relative to other elements for clarity. Further, if considered appropriate, reference numerals have been repeated among the figures to indicate corresponding and/or analogous elements.

The terminology used herein is for the purpose of describing some example embodiments only and is not intended to be limiting of the claimed subject matter. As used herein, the singular forms “a,” “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

It will be understood that when an element or layer is referred to as being on, “connected to” or “coupled to” another element or layer, it can be directly on, connected or coupled to the other element or layer or intervening elements or layers may be present. In contrast, when an element is referred to as being “directly on,” “directly connected to” or “directly coupled to” another element or layer, there are no intervening elements or layers present. Like numerals refer to like elements throughout. As used herein, the term “and/or” includes any and all combinations of one or more of the associated listed items.

The terms “first,” “second,” etc., as used herein, are used as labels for nouns that they precede, and do not imply any type of ordering (e.g., spatial, temporal, logical, etc.) unless explicitly defined as such. Furthermore, the same reference numerals may be used across two or more figures to refer to parts, components, blocks, circuits, units, or modules having the same or similar functionality. Such usage is, however, for simplicity of illustration and case of discussion only; it does not imply that the construction or architectural details of such components or units are the same across all embodiments or such commonly-referenced parts or modules are the only way to implement some of the example embodiments disclosed herein.

Unless otherwise defined, all terms (including technical and scientific terms) used herein have the same meaning as commonly understood by one of ordinary skill in the art to which this subject matter belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

“Polar code” as used herein refers to a forward-error-correcting code produced by applying a polar transform to a sequence, optionally in combination with a precoder (in which case, the result is a pre-coded polar code, such as a PAC code) and rate-matching operations. Some examples of “polar code” are a binary polar code, a PAC code that includes a rate-1 convolutional precoder, or polar variants using mixed kernels or non-binary alphabets.

“Polar code rate profile” as used herein refers to a specification of which codeword indices carry information-bits and which indices are treated as frozen prior to encoding. Some examples of “polar code rate profile” are an index set for a given code length and message length, a profile constructed by component partitioning with per-component counts, and a profile selected from reliability-ordered catalogs.

“Codeword” as used herein refers to the length-N encoded sequence output by an encoder that may include a rate-profiling stage, a precoder, and a polar transform, and that may be subject to puncturing or shortening prior to transmission. Some examples of “codeword” are an encoded block prior to modulation, a punctured encoded block sent over a channel, and a shortened frame produced for latency or bandwidth constraints.

“Allocation tuple” as used herein refers to an ordered list that specifies, for each component of a partition of the codeword positions, a count of information-bit positions assigned to that component, with the counts summing to the message length. Some examples of “allocation tuple” are (1, 3) for two components of size four, (2, 2) for two components of size four, and (1, 1, 1, 1) for four components of size four.

“Information set of a component code” as used herein refers to a subset of local indices within a component that are designated to carry information-bits for that component based on a specified count and a predetermined catalog for that component. Some examples of “information set of a component code” (which are described below in more detail) are, for a catalog where [symbol] (1)={2} and [symbol] (2)={1, 3}, are {2} in a length-4 component when the count is one, and {1, 3} in a length-4 component when the count is two.

“Global information index set” as used herein refers to the set of global codeword indices obtained by mapping each information set of a component code from its component's local index space to the full codeword index space. Some examples of “global information index set” (which are described below in more detail) are {2, 4, 6, 7} for counts (1, 3) across two components of size four, and {1, 3, 5, 7} for counts (2, 2) across the same partition.

“Rate-profiling module” as used herein refers to hardware, firmware, or software configured to populate a length-N vector by inserting message bits at indices in the global information index set and placing predetermined symbols (e.g., frozen zeros or CRC bits) at remaining indices, for input to a precoder and polar transform. Some examples of “rate-profiling module” are a firmware routine in a baseband processor, a hardware register-transfer level (RTL) block in an encoder pipeline, and a software library function executed by a processor.

“Candidate designs” as used herein refers to proposed configurations considered by a design procedure, each configuration comprising at least an allocation tuple and the corresponding global information index set. Some examples of “candidate designs” are an initial allocation tuple seeded from a template, a tuple produced by transferring one information position between components, and a set of tuples explored during a search or learning process.

“Predetermined catalog” (or “catalog”) ( [symbol] (k) or B (k), where “ [symbol] ” and “B” may be used interchangeably) as used herein refers to a data structure that, for a given component size and each possible count of information-bit positions, provides an information set of a component code and/or an ordering from which the set is derived. For example, each catalog entry may specify a reliability ordering of a component code that may include positions from most to least reliable, from which a corresponding information set can be selected. Some examples of “predetermined catalog” are tables that specify [symbol] (0) through [symbol] (size) for a length-4 component, a list of reliability-ordered indices stored in memory, and masks generated offline from analysis or simulation.

“An episode” as used herein refers to a finite sequence of design-procedure steps beginning from an initial allocation tuple and applying a fixed or bounded number of updates to produce a selected allocation tuple and its global information index set. Some examples of “an episode” are a 30-move sequence at a design SNR and a run that starts from a uniform allocation and ends after a predefined step.

“List-based decoder” as used herein refers to a decoder that maintains multiple candidate decoding paths in parallel (a list). A list-based decoder may include, for example, an SCL decoder, in which candidate paths are extended and pruned to maintain a maximum list size, or a CRC-aided SCL decoder, in which a CRC is applied to candidate paths to assist in path selection.

The disclosed systems and methods may be applied in a variety of communication environments, including wireless cellular systems (e.g., fourth generation (4G), fifth generation (5G), and beyond), satellite communication links, IoT networks, and other digital data transfer contexts. These environments can benefit from improved rate profile design because forward-error correction performance affects latency, throughput, energy efficiency, and robustness under diverse operating conditions.

Various embodiments relate to designing rate profiles for pre-coded polar codes, such as PAC codes. A rate profile may specify which bit positions of a length N codeword carry information-bits for a length K message and which positions are frozen.

More particularly, the present disclosure introduces a rate-profile design PAC codes by simplifying the construction of an information set (“A” or “ [symbol] ” may be used interchangeably to refer to an information set) for a PAC code of codeword length N into the design of information sets for M component codes, each component code having a component length equal to N/M, where the component length corresponds to the number of codeword bit positions included in that component code. The disclosure also defines a Markov decision process (MDP) that formulates the task of identifying the inf set that minimizes the BLER. To achieve this, a deep Q-network (DQN) can be used with an experience replay buffer to determine the optimal information set with the lowest BLER. These designed PAC codes improve BLER compared to state of the art PAC codes. This system and method is not limited to the design of PAC code information set; it is applicable to inf set design for the general family of pre-coded polar codes and supports various types of decoders.

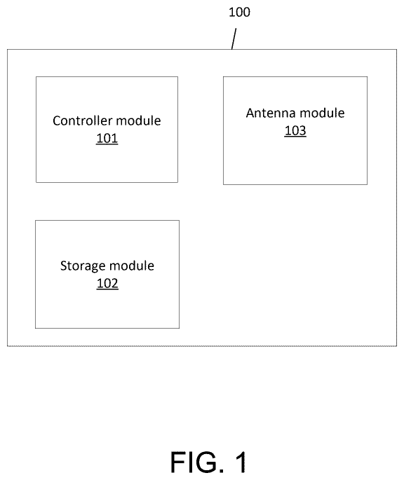

FIG. 1 illustrates a transmitting device or a receiving device in a communication system, according to an embodiment.

Referring to FIG. 1, the device 100 may operate as a base station, a UE, or a computing node (e.g., edge server, test bench, or design workstation) that implements code construction, decoding, and/or learning-based rate-profile design. The device 100 includes a controller module 101 (e.g., one or more processors), a storage module 102, and an antenna module 103. In various embodiments, the device 100 may be configured to transmit or receive codewords produced by a rate-profiling pipeline and/or to execute a design engine that selects information-bit locations for a code of length N and message length K.

The controller module 101 may perform processing tasks associated with PAC/polar code operation and design. For example, the controller module 101 may execute an encoder pipeline that performs rate profiling to populate an information set A, applies a precoder (e.g., a rate-1 convolutional precoder), and performs a polar transform to generate coded bits. The controller module 101 may also execute a decoder (e.g., SCL or CRC-aided SCL) and rate-matching logic (e.g., puncturing or shortening). In some embodiments, the controller module 101 may further implement a learning-based optimizer that evaluates candidate allocations, updates a policy or heuristic based on performance metrics such as BLER, and outputs a selected information set A for deployment.

The storage module 102 may include transitory or non-transitory memory storing executable instructions and data structures used for code operation and design. Examples include precoder definitions, decoder configurations, reliability catalogs for component partitions, tuples specifying per-component allocations, designed information sets A, channel-model parameters and/or SNR grids, rate-matching patterns, and logs or checkpoints from training and evaluation runs. The storage module 102 may further store protocol-stack elements and device-control parameters when the device 100 participates in an over-the-air system.

The antenna module 103 may include one or more antennas configured to wirelessly transmit and/or receive signals that carry coded data, pilots, and control information. When the device 100 functions as a base station or UE, the antenna module 103 may interface the encoder/decoder pipeline to the air interface. When the device 100 functions as an offline node, the antenna module 103 may be omitted or inactive, and the controller module 101 may still operate.

Polar codes may be created based on the concept of 0-1 rate assignment of bit channels, meaning that setting Rᵢ=0 corresponds to fixing the input to the i-th bit channel Wᵢ. Setting Rᵢ=1 corresponds to sending information in uncoded form over the i-th bit-channel Wᵢ.

PAC codes are often used because 0-1 rate assignments waste the capacities C(Wᵢ) of bit-channels Wᵢ whose inputs are fixed by the rate assignment Rᵢ=0. The capacity loss can be especially significant at practical (small to moderate) block-lengths N since polarization takes place relatively slowly. In order to prevent such capacity loss, a need exists for a scheme that avoids fixing the input of any bit-channel. PAC codes may achieve this by placing an outer convolutional coding block with rate 1 in front of the polar transform.

PAC code design can be seen as serially concatenating an outer convolutional code with an inner Polar code. Herein, list decoding is used for PAC codes instead of sequential decoding.

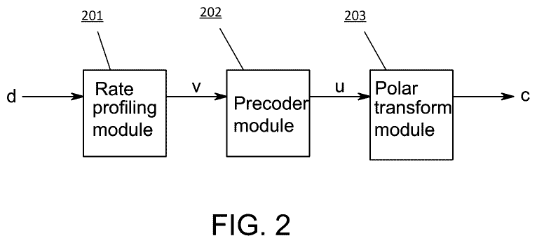

FIG. 2 illustrates an example encoding pipeline for PAC codes, according to an embodiment.

Referring to FIG. 2, a message vector d of length K may be processed by a rate profiling module 201 that maps the K information-bits into selected positions of a length-N vector v. Positions in v not allocated to information may be populated with predetermined symbols (e.g., frozen zeros and, when used, CRC bits). The choice of which indices carry information (i.e., the information set A) may be provided by the design described herein and can be derived from a component partition with per-component allocations.

The vector v may then be provided to a precoder 202, which produces an intermediate sequence u (e.g., via a rate-1 convolution defined by a selected impulse response). The sequence u may be supplied to a polar transform module 203 that generates a length-N codeword c for transmission. In some embodiments, rate-matching (e.g., puncturing or shortening) may be applied to c prior to transmission, and corresponding inverse processing may be applied at a receiver.

According to an embodiment, for a (N, K) PAC code, N is the block length such that N=2ⁿ, n≥1, and K is the code dimension such that 1≤K≤N. The encoding operation for PAC codes is as follows. A rate-profiling block inserts the source word d=[d₀, d₁, . . . , d_{K-1}] into a data carrier word v=[v₀, v₁, . . . , v_{N-1}] in accordance with an information index set [symbol] ⊂ {0, 1, . . . , N-1}, | [symbol] |=K so that v [symbol] =d and v [symbol] ^{c}=0. Selection of K indices out of N possible indices may be referred to as rate-profile design. The vector u is obtained from v by a one-to-one convolution operation, which can be characterized by an impulse response g=[g₀, . . . , gₘ], where g₀=1 and gₘ=1. The input-output relation can be represented as

$${u}_{i} = {\sum }_{j = 0}^{m} {g}_{j} {v}_{i - j} ,$$

for 0≤i≤N-1, where vₖ=0 for k<0 by convention. The codeword c can be obtained from vector u using c=uP^{⊗n}, where Pₙ=P^{⊗n} is the polar transform defined as the nth Kronecker power of

$$P = [ \begin{matrix}1 & 0 \\ 0 & 1\end{matrix} ] .$$

The convolution operation can be characterized by an impulse response g=(g₀, . . . , gₘ), where it is assumed that g₀≠0 and gₘ≠0. The parameter m+1 may refer to the constraint length of the convolution. The input-output relation can be represented by one or more of Equations 1-3.

$${u}_{i} = {\sum }_{j = 0}^{m} {g}_{j} {v}_{i - j} \qquad Equation 1$$

$$u = vG \qquad Equation 2$$

$$G = [ \begin{matrix}{g}_{0} & {g}_{1} & {g}_{2} & … & {g}_{m} & 0 & … & 0 \\ 0 & {g}_{0} & {g}_{1} & {g}_{2} & … & {g}_{m} & & ⋮ \\ 0 & 0 & {g}_{0} & {g}_{1} & ⋱ & … & {g}_{m} & ⋮ \\ ⋮ & 0 & ⋱ & ⋱ & ⋱ & ⋱ & & ⋮ \\ ⋮ & & ⋱ & ⋱ & ⋱ & ⋱ & 0 & ⋮ \\ ⋮ & & & & 0 & {g}_{0} & {g}_{1} & {g}_{2} \\ ⋮ & & & & 0 & 0 & {g}_{0} & {g}_{1} \\ 0 & … & … & … & … & 0 & 0 & {g}_{0}\end{matrix} ] \qquad Equation 3$$

To illustrate the above encoding operation, for example, consider N=8, K=4, B={4, 6, 7, 8}, and g=(1, 1, 1). The rate-profiler maps the source word d=(d₁, . . . , d₄) into v=(v₁, . . . , v₈) so that v=(0, 0, 0, d₁, 0, d₂, d₃, d₄).

The convolution u=vG generates an output word u with u₁=v₁, u₂=v₁+v₂, and uᵢ=vᵢ₋₂+vᵢ₋₁+vᵢ for i=3, . . . , 8. Encoding is completed by computing the polar transform x=uP₃.

A PAC code may be specified by four parameters (N, K, [symbol] , g). Determining effective design rules for [symbol] , (i.e., rate-profile design) can be challenging. For example, the performance of a PAC code may be more sensitive to the choice of [symbol] than to g.

In addition, the performance of a PAC code may be more sensitive to the choice of B than to g. As long as the constraint length of the convolution (m+1) is sufficiently large, choosing g at random may be an acceptable design practice. However, determining effective design rules for B can also be challenging.

The present disclosure focuses on list decoding of PAC codes, which has practical advantages of other decoding methodologies (e.g., Fano decoding). In particular, a Fano decoder tends to have SNR-dependent time complexity with high complexity at low SNRs. This is not desirable for low-SNR regimes, when a worst case decoding latency may be needed to be ensured. In addition, embodiments introduced herein may be applied and operate with various types of other decoders.

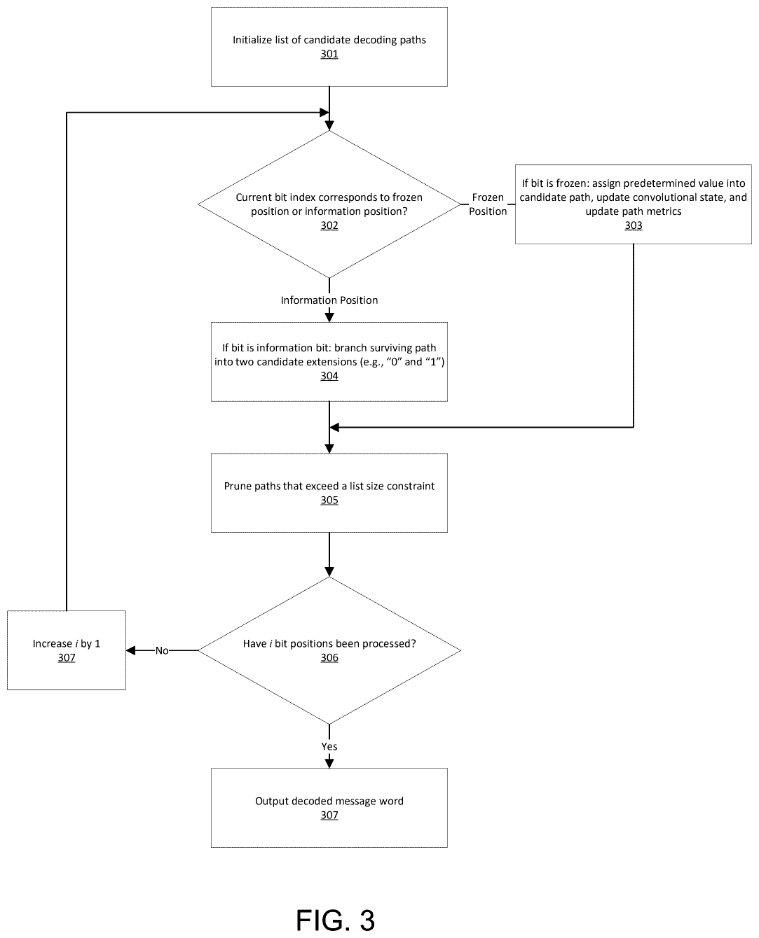

FIG. 3 is a flowchart illustrating a list decoding approach, according to an embodiment.

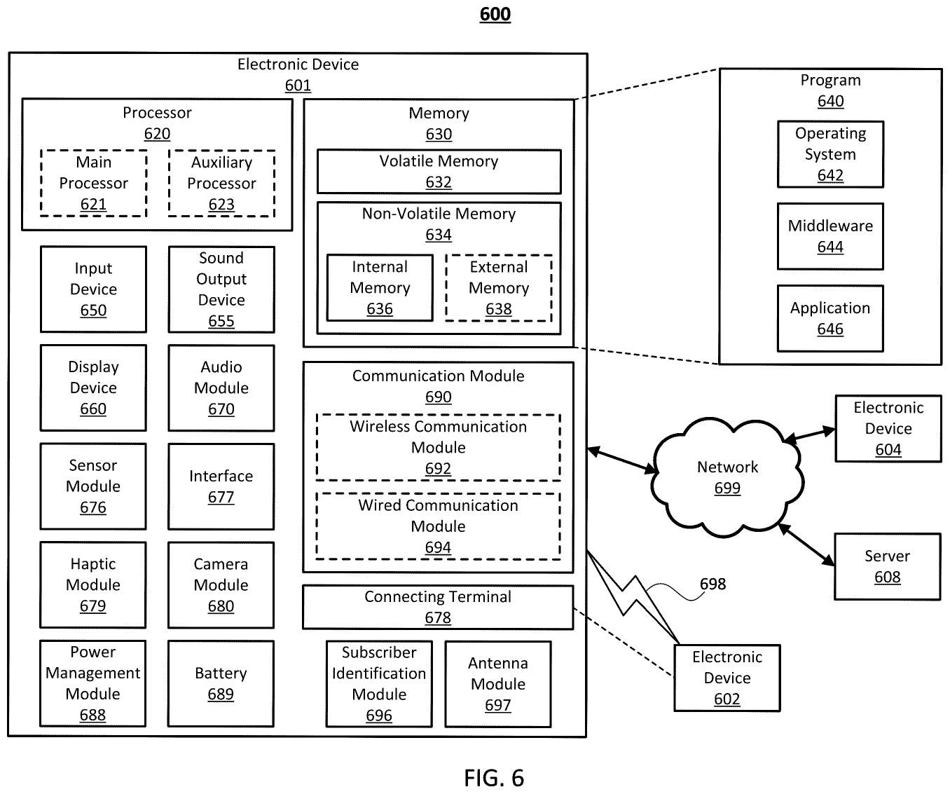

The operations of FIG. 3 may be executed by a decoder that may be included in an electronic device, such as the processor and memory arrangement shown in FIG. 6. For example, list initialization, branching, metric updating, and pruning may be carried out by software on a central processing unit (CPU) or digital signal processor (DSP), or by hardware logic in a baseband processor or accelerator.

Referring to FIG. 3, at step 301, a decoder may initialize a list of candidate decoding paths. For example, this may involve creating a single starting path that assumes no bits have yet been decided, with an initial path metric (a numerical representation of decoding likelihood for a candidate path, which may be updated using log-likelihood ratios (LLRs) and used to rank or prune paths during list decoding) set to zero and an empty state vector representing the convolutional pre-coder memory.

At step 302, the decoder may determine whether the current bit index corresponds to a frozen position or an information position based on the rate profile. For example, if the rate profile specifies that index i is frozen, the decoder may treat it as predetermined (e.g., set to zero), whereas if index i is in the information set, the decoder may prepare to branch on multiple candidate values.

At step 303, if the bit is frozen, the decoder may update the path states accordingly. For example, the decoder may insert the frozen “0” into each candidate path, apply a convolutional transform defined by the PAC pre-coder, and update LLRs or other path metrics to reflect the known input.

At step 304, if the bit is an information-bit, the decoder may branch each surviving path into two candidate extensions, one assuming a “0” and another assuming a “1”. For example, the decoder may duplicate the current path, insert each bit hypothesis, compute updated LLR-based metrics for both paths, and store partial sums for later decoding stages.

At step 305, the decoder may evaluate and prune the number of paths that exceed a list size constraint. For example, in a list size L=8 decoder, if branching produces more than 8 paths, the decoder may prune by retaining only the 8 with the most favorable metrics and discarding the others.

At step 306, the decoder may repeat this process iteratively until all i bit positions have been processed. For example, for a codeword length of i=128, the decoder may loop through steps 302-305 a total of 128 times, progressively increasing i by 1 in step 307 until i bit positions have been processed.

At step 308, the decoder may output the decoded message word from the most likely surviving path in the list. For example, the final decision may be taken from the path with the lowest accumulated path metric, which corresponds to the highest estimated likelihood under the channel conditions.

According to an embodiment, the flowchart of FIG. 3 can be implemented based on the following Routine 1, below.

```
Routine 1: List Decoding of PAC Codes.
$input : channel LLRs {λ}_{n}^{0 , N - 1} , β , L , g$
output: recovered message bits \hat{d} [symbol]
  ← {1} // a single path in the list
$[ λ , β ] ← \{ [ {λ}_{n}^{0 , N - 1} + \{ 0 \} , \{ 0 \} ] \}$
for i ← 0 to N − 1 do
  if i ∉ [symbol]   then
    for l ← 1 to | [symbol]   | do
      λ₀ⁱ[l] ← updateLLRs(l, i, λ[l], β[l])v
      \hat{v}ᵢ[l] ← 0
      [ûᵢ[l], cState[l] ← conv1b Trans(vᵢ, cState[l], g)
      $P {M}_{l}^{( i )} ← c a l c P M ( P {M}_{l}^{( i - 1 )} , {λ}_{0}^{i} [ l ] , {\hat{u}}_{i} [ l ] )$
      β[l] ← updatePartialSums(ûᵢ[l], β[l])
  else
    for l ← 1 to | [symbol]   | do [symbol]
        ← duplicatePath( [symbol] , l, i, g)
    if | [symbol]   | > L then [symbol]
        ← prunePaths( [symbol]  ) / like SCLD
$\hat{d} ← extractData ( {\hat{v}}_{1}^{N} [ 0 ] )$
return \hat{d}
subroutine duplicatePath( [symbol] , l, i, g): [symbol]
    ← [symbol]   ∪ {l′} // path l′ is a copy of path l
  ${λ}_{0}^{i} [ l ] ← update LLRs ( l , i , λ [ l ] , β [ l ] )$
  [\hat{v}ᵢ[l], \hat{v}ᵢ[l′] ← {0, 1}
  [ûᵢ[l], cState[l]] ← conv1bTrans(\hat{v}ᵢ[l], cState[l], g)
  [ûᵢ[l′], cState[l′]] ← conv1bTrans(\hat{v}ᵢ[l′], cState[l], g)
  $P {M}_{l}^{( i )} ← c a l c P M ( P {M}_{l}^{( i - 1 )} , {λ}_{0}^{i} [ l ] , {\hat{u}}_{i} [ l ] )$
  $P {M}_{l r}^{( i )} ← c a l c P M ( P {M}_{l}^{( i - 1 )} , {λ}_{0}^{i} [ l ] , {\hat{u}}_{i} [ {l}^{′} ] )$
  β[l] ← updatePartialSums(ûᵢ[l], β[l])
  β[l′] ← updatePartialSums(ûᵢ[l], β[l])
  return [symbol]
subroutine calcPM(PM, λ₀, û):
  if û = 1/2 (1 − sgn(λ₀)) then
    PM = PM
  else
    PM = PM + |λ₀|
  return PM
```

Referring to Routine 1 above, at the start, there may be a single path in the list and decoder state values (e.g., LLR buffers and partial sums) may be initialized (e.g., to zero). When the index of the current bit is in the set B^{c} (e.g., not in the information set), the decoder may treat the bit as frozen (e.g., vᵢ=0) and therefore it may be encoded into uᵢ based on the current memory state (e.g., currState) and the generator polynomial g. Then, using the decision LLR

$${λ}_{0}^{i} ,$$

the corresponding path metric may be calculated using subroutine calcPM, and the decoded value uᵢ may be fed back into a successive-cancellation process to calculate partial sums. On the other hand, if the index of the current bit is in the set B, there may be two options for the value of vᵢ, 0 and 1 (e.g., the path list may branch for one or both hypotheses). For example, for each option of 0 and 1, the aforementioned process for iϵB_{c} including convolutional encoding and calculating path metric, may be performed and then the encoded values corresponding to vᵢ=0 and 1 may be fed back into a successive-cancellation decoding process to update partial sums. If branching produces more than a maximum size list L, the decoder may prune candidate paths to retail at most L (e.g., via prunePaths). The subroutines updateLLRs, updatePartialSums, and prunePaths may be similar to ones used in successive-cancellation decoding and SCL decoding of polar codes.

The process of list decoding for PAC codes may be similar to that for polar codes except for the additional convolutional re-encoding at each decoding step for which the next memory state is stored for each path. Conceptually, this may be equivalent to having two lists that are kept at the decoder, one for u and another one for v.

In accordance with an embodiment, the disclosure breaks down the design of rate-profiler for length N PAC code [symbol] into rate-profilers for M component codes [symbol] ᵢ, iϵ{1, 2, . . . , M} such that N/M is an integer. The design of rate-profiler for (N, K) PAC code may then depend on designing information/frozen set pattern for all the component codes, such that the component codes collectively include K information-bits. By concatenating the component-level information sets selected from the catalog, the global information index set A for the (N, K) code is obtained. For example, for (N=8, K=5) code with rate profiler B, let M=2. If the component codes [symbol] ₁ and [symbol] ₂ with length 4 have information sets A₁′=B₁(K₁)={1,3,4} and A₂′=B₂(K₂)={2,3}, then the global information index set A is obtained by concatenating A₁′ and A′₂ with an offset applied to the second component, which yields {1,3,4,6,7}.

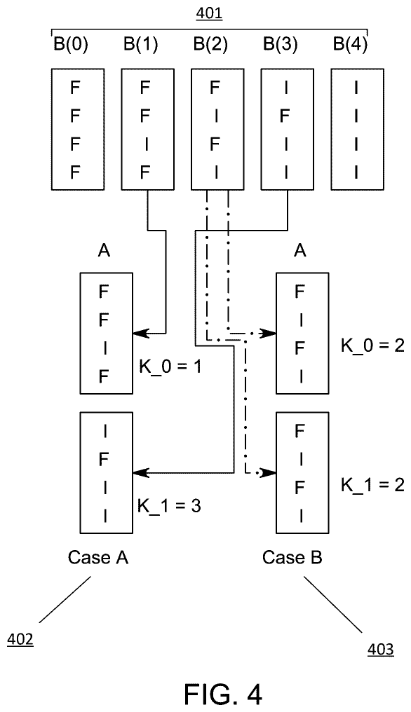

FIG. 4 illustrates an example construction of an information index set for a length-N=8 codeword with message length K=4 that is partitioned into M=2 components of equal size, according to an embodiment.

In this embodiment, the length-N codeword may be viewed as comprising a set of N bit positions, each position corresponding to an index in the codeword vector. The set of codeword bit positions may be partitioned into multiple components, each component corresponding to a disjoint subset of the positions. For example, when N=8, the codeword bit positions may be partitioned into two components equal in size of length 4 each. An allocation tuple (K₀, K₁) may then specify how many information-bits are assigned to the first component and to the second component, respectively, for each of the components. In addition, each component may be associated with an information set of a component code identifying which of its bit positions carry information-bits.

Referring to FIG. 4, the top row 401 depicts a reliability index catalog (e.g., including a reliability ordering of positions) for a length-4 component, denoted [symbol] (0) to [symbol] (4). Each [symbol] (k) identifies, in local (component) indices {0,1,2,3}, the k positions that would be populated first with information-bits for that component.

In this example, [symbol] (0)={ }, [symbol] (1)={2}, [symbol] (2)={1,3}, [symbol] (3)={0, 2, 3}, [symbol] (4)={0, 1, 2, 3}. The “I”/“F” stacks in the figure visually represent these masks (I=information position, F=frozen position).

Two allocation cases for the two components (component 0 covering global indices {0,1,2,3} and component 1 covering global indices {4,5,6,7}) are shown. For each component i, a chosen cardinality Kᵢ selects a local information set

$${𝒜}_{i}^{′} = ℬ ( {K}_{i} ) .$$

The global information index set is then obtained by concatenating the two local information sets with the appropriate offset for component 1 (i.e., adding +4 to its local indices). This mapping of local indices to global indices preserves the relative ordering of positions within each component while embedding them into the full codeword index space.

In Case A 402, the solid arrows indicate K₀=1 and K₁=3. From the catalog 401.

$${𝒜}_{0}^{′} = ℬ ( 1 ) = \{ 2 \} and {𝒜}_{1}^{′} = ℬ ( 3 ) = \{ 0 , 2 , 3 \} .$$

Applying the offset to

$${𝒜}_{1}^{′}$$

gives {4,6,7}, so the concatenation yields {2,4,6,7}. The two “A” stacks in the left column depict, respectively, one “I” within component 0 and three “I”'s within component 1.

In Case B 403, the dotted arrows indicate K₀=2 and K₁=2. From the catalog 401,

$${𝒜}_{0}^{′} = ℬ ( 2 ) = \{ 1 , 3 \} and {𝒜}_{1}^{′} = ℬ ( 2 ) = \{ 1 , 3 \} .$$

Offsetting the second component's local indices gives {5,7}, so the concatenation yields {1,3,5,7}. Accordingly, each allocation tuple (e.g., (K₀, K₁)) defines a generated global information index set obtained by concatenating an information set of a component code with offsets applied to their local indices. The two “A” stacks in the right column depict two “I” positions selected in each component.

Accordingly, FIG. 4 exemplifies how partitioning the N positions into components allows the rate-profile design to be specified by the tuple (K₀, K₁) instead of enumerating all N possibilities. Given the predetermined reliability catalog [symbol] , each (K₀, K₁) uniquely determines the global set [symbol] , and different tuples (e.g., (1,3) versus (2,2)) lead to different [symbol] sets as shown.

Additionally, according to an embodiment, each component code Cᵢ (iϵ{1, 2, . . . , M}) may have Kᵢ information-bits

$$( 0 \leq {K}_{i} \leq \frac{N}{M} ) .$$

The rate-profiler may be a function of a number of information-bits included in the component code (i.e., parameter Kᵢ). Therefore, the rate-profiler for component code Cᵢ can be denoted by Bᵢ(Kᵢ).

$$\frac{N}{M} = 4$$

For example, for N=8, K=5, M=2 component codes [symbol] ₁ and [symbol] ₂ with length can be assumed. [symbol] ₁ and [symbol] ₂ may have 0≤K₁, K₂≤5 information-bits and in total both component codes have K₁+K₂=5 information-bits. Also, a total of

$$\frac{N}{M} + 1 = 5$$

patterns B(Kᵢ) of length

$$\frac{N}{M} = 4$$

may be required to cover all the possible cases for K₁ and K₂. The following is an example for all the 5 cases: For Bᵢ(0)={ }, Bᵢ(1)={3}, Bᵢ(2)={2,3}, Bᵢ(3)={1,3,4}, Bᵢ(4)={1,2,3,4}. If K₁=3, and K₂=2, then B={1,3,4,6,7}.

Based on this formulation, an MDP can be defined as follows:
State: An M-tuple s=(K₁, K₂, . . . , K_{M}) may represent the state, such that ΣKᵢ=K, and

$$0 \leq {K}_{i} \leq \frac{N}{M} .$$

This state may also be referred to as a current allocation tuple, which specifies the counts of information positions assigned to the respective components at a given stage of the design process.
Action: An ordered pair a=(i, j) defines the action a, where 1≤i, j≤M, and it identifies a source component code [symbol] ᵢ and a destination component code [symbol] ⱼ. This can mean that 1 information-bit is removed from [symbol] ᵢ and 1 information-bit is added to [symbol] ⱼ. Accordingly, the new rate allocation s′ may be obtained from s by changing Kᵢ←Kᵢ−1, Kⱼ←Kⱼ+1.
Reward: This may represent the BLER reduction from current state s to the next state s′ via the action a (i.e., r=BLER(s′)−BLER(s)), where s′ is deterministically given by s and a.

The block-error performance may be quantified as a BLER, which can be measured for each constructed global information index set derived from a current allocation tuple. The allocation tuple corresponding to the lowest measured BLER within a design episode may then be selected as the preferred tuple. The BLER, for example, can be calculated via a Monte Carlo simulation for each state

This MDP with any possible solution is applicable to scenarios given any initial state, rate-profilers of component codes, and/or decoder.

According to an embodiment, an RL solution for the defined MDP may be DON with a replay buffer.

In accordance with an embodiment, an RL agent starts from a given initial state sᵢₙᵢₜ, and after T steps the agent stops. A neural network Q with weights θ may be chosen. The input to Q may be state s with dimension M and the output may be the Q-value of actions a, with dimension M². State space size for any K may be based on the coefficient of x^{K} in polynomial expansion of

$${( 1 + x + … + {x}^{\frac{N}{M}} )}^{M} ,$$

and the action space size may be M².

For example, the following pseudocode can be applied to train Q.

```
  Input: T, Code parameters (N, K, M), number of episodes E, and ϵ, τ, γ
  Initialize sᵢₙᵢₜ
  Initialize replay memory [symbol]   to 5 × batch_size
  Initialize action-value function Q with random weights θ
  Initialize target action-value function \hat{Q} with weights θ⁻ = θ
  For episode = 1, ... , E do
    s₁ = sᵢₙᵢₜ
    For t=1, ... , T do
  With probability ϵ select a random action aₜ
  $Otherwise select {a}_{t} = {arg max}_{a} Q ( {s}_{t} , a ; θ )$
  Store transition (sₜ, aₜ, rₜ, sₜ₊₁) in [symbol]
      Sample a random minibatch of transitions (sⱼ, aⱼ, rⱼ, sⱼ₊₁) in [symbol]
      $Set {y}_{j} = {r}_{j} + γ {max}_{{a}^{′}} \hat{Q} ( {s}_{j + 1} , {a}^{′} ; {θ}^{-} )$
    Perform a gradient descent update step on (yⱼ − Q(sⱼ, aⱼ; θ))² with
repect to θ to update Q.
  Update \hat{Q} = (1 − τ)\hat{Q} + τQ
  End for
  End for
  Return Q
```

At each episode of the RL routine above, BLER may be calculated at T time-steps. As the episode increases, the state with the minimum value of BLER may be tracked, and the output may be reported after E episodes. The rate-profiler corresponding to this state may be the final code.

According to an embodiment, one example for the choice of information patterns [symbol] _{K}_{ᵢ} for

$$0 \leq {K}_{i} \leq \frac{N}{M}$$

for component codes of length N/M can be based on the information pattern of 5G-new radio (NR) polar code for length N/M, or any other information pattern for length N/M with a BLER performance that meets or exceeds a predetermined threshold.

For example, for the case of (256,128) code with M=16, there are 16+1 patterns as follows based on a 5G-NR information pattern for length

$$\frac{256}{16} = 16 codes .$$

Each Bᵢ(Kᵢ) may correspond to rate profile(s) of

$$( \frac{N}{M} , {K}_{i} )$$

5G-NR code described below:

$${B}_{i} ( 0 ) = \{ \}$$

$${B}_{i} ( 1 ) = \{ 16 \}$$

$${B}_{i} ( 2 ) = \{ 15 , 16 \}$$

$${B}_{i} ( 3 ) = \{ 14 , 15 , 16 \}$$

$${B}_{i} ( 4 ) = \{ 12 , 14 , 15 , 16 \}$$

$$⋮$$

$${B}_{i} ( 16 ) = \{ 1 , 2 , … , 16 \}$$

The initial state sᵢₙᵢₜ may represent a PAC code with good performance, so that the DQN can learn to improve upon this code to find a possibly better performing code. For a well performing code, such as an (N, K) code in 5G-NR, it can be broken down to M components, and for each component, count the number of 1's, referred to as

$${K}_{i}^{init} ,$$

may be formed as sᵢₙᵢₜ follows in Equation 4.

$${s}_{init} = [ {K}_{1}^{init} , {K}_{2}^{init} , ... , {K}_{M}^{init} ] \qquad Equation 4$$

The DON can be a multi-layer perceptron (MLP) for simplicity, or a convolutional neural network (CNN). Any other desired neural network may also be selected.

According to an embodiment, the DQN may select the action with highest Q-value at its output. However, for certain states, there may exist actions that can send the agent to a non-valid state. To be more specific, if Kᵢ=0 or

$${K}_{j} = \frac{N}{M} ,$$

the selected action may set the next state values to Kᵢ=−1 or

$${K}_{j} = \frac{N}{M} + 1 ,$$

which are not valid. To prevent the selection of such actions, a mask may be used at the output of DQN that sets the Q-value of such actions for any input state to −∞.

In certain embodiments, the action-value function may be implemented by a neural network whose input dimension equals the number of components M and whose output enumerates M² actions corresponding to ordered pairs (i, j). In one example, a linear projection maps input dimension M to M², followed by five one-dimensional CNN layers having a kernel size of 5 and 100 filters per layer; a final linear layer maps each action channel to a scalar value. Each CNN layer and the output layer may be followed by a rectified linear unit (ReLU) activation. Other function approximators (different layer counts, kernel sizes, filter counts, graph neural networks, and/or transformers) may be used.

Training may employ a DQN with a replay buffer. In one representative configuration, the optimizer may be AdamW (a type of optimizer used to train neural networks), the loss may be a Huber loss (e.g., SmoothL1), the discount factor γ may be 0.99, the soft target-network update coefficient t may be 0.005, the mini-batch size B may be 128, the replay buffer capacity may be 3,000 transitions, and each episode may have a horizon T=30 steps. An exploration rate ϵ may decay over total time steps tₜₒₜₐₗ=t+T. ( [symbol] −1) according to Equation 5.

$$ϵ = {ϵ}_{end} + ( {ϵ}_{start} - {ϵ}_{end} ) \cdot {e}^{- \frac{{t}_{total}}{{ϵ}_{decay}}} \qquad Equation 5$$

In Equation 5, ϵₛₜₐᵣₜ=0.9, ϵ_{end}=0.001, and ϵ_{decay}=300. The number of components M may be selected heuristically, for example M=8 or M=16; other values may be used.

For design-time evaluation, a single “design SNR” point may be selected such that the resulting BLER under the target decoder falls within a nominal range (e.g., 5×10⁻³, 5×10⁻²); the profile obtained at that SNR may then be evaluated across a broader SNR sweep to produce BLER-versus-SNR curves.

Furthermore, although SCL decoding is discussed comprehensively in this disclosure, various embodiments disclosed herein are compatible with any decoder applicable to PAC codes, including SC, SCL, CA-SCL, or sequential decoding.

According to an embodiment, an example code design will now be described.

Consider a (256,128) PAC code with g=(1 1 0 1 0 0 0 1 0 0 1), decoded with SCL decoder (L=8). The remaining parameter left to be determined is the rate-profile to completely specify this code. The rate profile may be designated with the method disclosed herein with the following design parameters:

For M=16, and CNN-based neural network for Q, a rate-profile of each sub-code may be designed based on 5G-NR code for

$$\frac{N}{M} = 16$$

as described in the example case above. The initial state may also be derived from a (256,128) 5G-NR code. The network may be trained for 1000 episodes each with T=30 time steps.

Training may be performed at SNR=2 decibels (dB), and the BLER vs SNR may be plotted for this code for all SNRs. The codes designed with the method disclosed herein often performs better than the codes designed at SNR 2 dB.

Furthermore, according to an embodiment, the search space of an RL agent may also be limited. One possibility is to restrict the search space using parameter & for each element of a visited state, providing:

$$\vert {S}_{init}^{i} - {S}^{i} \vert \leq δ ,$$

where Sⁱ is the i^{th} element of S, 1≤i≤M. This restriction can also be applied using a mask at the output of DQN that sets Q-values of actions that sends the agent to states that do not meet the criteria. Other restrictions to the search space are also possible.

Accordingly, various embodiments disclosed herein can be applied to polar codes, PAC codes, and/or various forms of pre-coded polar codes. As discussed above, solutions disclosed herein have been discussed for the case of PAC codes with a given pre-coder g as simplifying an information set for an (N, K) PAC code into design of M information sets for

$$( \frac{N}{M} , {K}_{i} )$$

component codes such that

$${\sum }_{i = 0}^{M - 1} {K}_{i} = K .$$

The information set choices may be restricted for the i th component code by making the information set fully specifiable by Kᵢ. Therefore, the information set design may be simplified to finding the optimal set of Kᵢs. Finding the optimal set of Kᵢs in terms of BLER minimization may be defined as a task within an MDP framework. DQN with an experience replay buffer may be utilized to perform the optimization task. The proposed designed PAC codes improve computational performance compared to state of the art PAC codes in terms of BLER for practical list size of L=8, for example. Furthermore, for less practical L E {32, 64}, the design disclosed herein may provide improved BLER performance, too. In addition, by setting g=[1], various solutions disclosed herein may be applicable to Polar codes, as well. In general, for pre-coded polar codes with the given pre-coder, the proposed solutions can be used for design of one or more information set(s).

This method is not limited to the design of PAC code information set(s), and it may be applicable to information set design for the general family of pre-coded polar codes and supports various types of decoders.

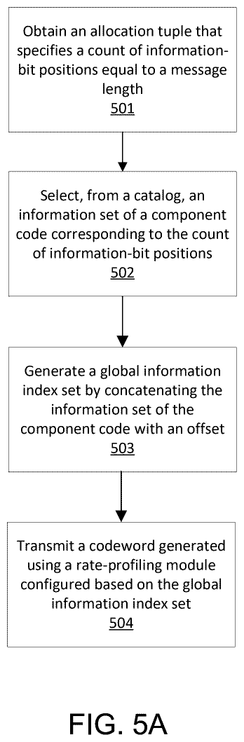

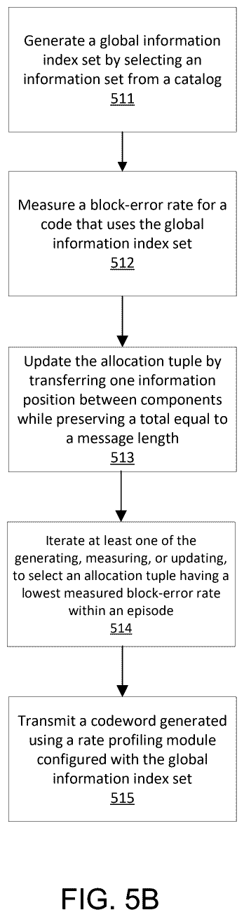

FIG. 5A is a flowchart illustrating a method of defining a rate profile of a pre-coded polar code, according to an embodiment.

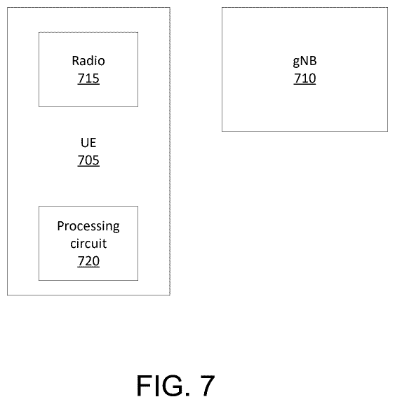

The steps of FIG. 5A may be performed by a processing circuit of an electronic device, such as the controller module 101 of FIG. 1, the processor 620 and memory 630 of FIG. 6, or the processing circuit 720 of FIG. 7. In some embodiments, these components may execute software instructions that configure a rate-profiling module and generate codewords for transmission via an associated communication module and/or antenna.

Referring to FIG. 5A, at step 501, an allocation tuple may be obtained that specifies, for at least one component of a plurality of components, a count of information-bit positions equal to a message length. For example, in FIG. 4 the allocation tuple (K₀, K₁) may define how many information bits are placed into each component of size N/M.

At step 502, for the at least one component, an information set of a component code corresponding to the specified count may be selected from a catalog. In some embodiments, the catalog may be a predetermined data structure that provides, for each possible count, a reliability-ordered subset of indices B(Kᵢ). For instance, if Kᵢ=2 in a length-4 component, the catalog may return {1, 3} as the information set.

At step 503, a global information index set may be generated by concatenating the information set of the component code with an offset (e.g., that maps the component-local indices to global indices of the codeword). For example, when a codeword of length N=8 is partitioned into M=2 components of length 4 each, and component 1 corresponds to global indices {4,5,6,7}, then if component 1's local information set is {0,2,3}, applying an offset of +4 (equal to the starting global index of that component) may yield the global information set {4,6,7}.

At step 504, a codeword may be transmitted via an encoder that includes a rate-profiling module configured based on the global information index set. For example, the rate-profiling module may insert message bits at positions in the global information index set and frozen symbols (e.g., zeros or CRC bits) before transmission.

FIG. 5B is a flowchart illustrating a method for designing an information index set of a pre-coded polar code, according to an embodiment.

The steps of FIG. 5B may be performed by a processing circuit of an electronic device, such as the controller module 101 of FIG. 1, the processor 620 and memory 630 of FIG. 6, or the processing circuit 720 of FIG. 7. The device may construct, evaluate, and update allocation tuples and corresponding information index sets based on block-error-rate measurements.

Referring to FIG. 5B, at step 511, for a current allocation tuple, a global information index set may be generated by selecting, for a component included in a plurality of components, an information set from a catalog. This process may follow a similar offset-based concatenation as described with reference to FIG. 4, producing a global information index for evaluation.

At step 512, a BLER may be measured for a code that uses the constructed global information index set. For example, a decoder such as an SCL or CRC-aided SCL decoder may be applied to test transmissions or simulated channel outputs, and the resulting error statistics may be logged as BLER values.

At step 513, the allocation tuple is updated by transferring one information position between components while preserving a total equal to the message length (where the total may correspond to a total number of information-bit positions). In one embodiment, this step may correspond to decrementing Kᵢ for a source component and incrementing Kⱼ for a destination component, as described in the Markov decision process formulation.

At step 514, one or more of the generating, measuring, or updating steps (corresponding to steps 511, 512, and 513, respectively) may be iterated to select an allocation tuple having the lowest measured BLER within an episode. This iteration may be performed using a reinforcement learning agent (e.g., a deep Q-network) or a heuristic search. As the episode progresses, candidate designs that reduce BLER may be tracked, and the allocation tuple with the best performance may be selected.

At step 515, a codeword may be transmitted using a rate-profiling module configured with the global information index set corresponding to the selected allocation tuple. The encoder may operate as described with respect to FIG. 2 by, for example, inserting message bits according to the optimized information set, applying convolutional pre-coding, and then performing a polar transform before transmission.

FIG. 6 is a block diagram of an electronic device in a network environment, according to an embodiment.

Referring to FIG. 6, an electronic device 601 in a network environment 600 may communicate with an electronic device 602 via a first network 698 (e.g., a short-range wireless communication network), or an electronic device 604 or a server 608 via a second network 699 (e.g., a long-range wireless communication network). The electronic device 601 may communicate with the electronic device 604 via the server 608. The electronic device 601 may include a processor 620, a memory 630, an input device 650, a sound output device 655, a display device 660, an audio module 670, a sensor module 676, an interface 677, a haptic module 679, a camera module 680, a power management module 688, a battery 689, a communication module 690, a subscriber identification module (SIM) card 696, or an antenna module 697. In one embodiment, at least one (e.g., the display device 660 or the camera module 680) of the components may be omitted from the electronic device 601, or one or more other components may be added to the electronic device 601. Some of the components may be implemented as a single IC. For example, the sensor module 676 (e.g., a fingerprint sensor, an iris sensor, or an illuminance sensor) may be embedded in the display device 660 (e.g., a display).

The processor 620 may execute software (e.g., a program 640) to control at least one other component (e.g., a hardware or a software component) of the electronic device 601 coupled with the processor 620 and may perform various data processing or computations.

As at least part of the data processing or computations, the processor 620 may load a command or data received from another component (e.g., the sensor module 676 or the communication module 690) in volatile memory 632, process the command or the data stored in the volatile memory 632, and store resulting data in non-volatile memory 634. The processor 620 may include a main processor 621 (e.g., a CPU or an application processor (AP)), and an auxiliary processor 623 (e.g., a graphics processing unit (GPU), an image signal processor (ISP), a sensor hub processor, or a communication processor (CP)) that is operable independently from, or in conjunction with, the main processor 621. Additionally or alternatively, the auxiliary processor 623 may be adapted to consume less power than the main processor 621, or execute a particular function. The auxiliary processor 623 may be implemented as being separate from, or a part of, the main processor 621.

The auxiliary processor 623 may control at least some of the functions or states related to at least one component (e.g., the display device 660, the sensor module 676, or the communication module 690) among the components of the electronic device 601, instead of the main processor 621 while the main processor 621 is in an inactive (e.g., sleep) state, or together with the main processor 621 while the main processor 621 is in an active state (e.g., executing an application). The auxiliary processor 623 (e.g., an image signal processor or a communication processor) may be implemented as part of another component (e.g., the camera module 680 or the communication module 690) functionally related to the auxiliary processor 623.

The memory 630 may store various data used by at least one component (e.g., the processor 620 or the sensor module 676) of the electronic device 601. The various data may include, for example, software (e.g., the program 640) and input data or output data for a command related thereto. The memory 630 may include the volatile memory 632 or the non-volatile memory 634. Non-volatile memory 634 may include internal memory 636 and/or external memory 638.

The program 640 may be stored in the memory 630 as software, and may include, for example, an operating system (OS) 642, middleware 644, or an application 646.

Furthermore, the processor 620 (e.g., main processor 621 with auxiliary processor 623) and the memory 630 may cooperatively implement a rate-profile design engine and a PAC/polar code pipeline. In particular, the processor 620 and the memory 630 may execute (i) the rate-profile construction depicted in FIG. 4 from a component allocation tuple (K₀, K₁, . . . , K_{M-1}) and a reliability catalog [symbol] , (ii) the encoding path of FIG. 2 (rate-profiling, convolutional pre-coding, and polar transform), and/or (iii) the list-decoding steps of FIG. 3 (steps 301-307). For example, the program 640 stored in the memory 630 may include modules that (i) construct an information index set [symbol] from per-component allocations, (ii) execute a convolutional precoder and polar transform for encoding, and (iii) perform list-based decoding (e.g., SCL or CRC-aided SCL) for evaluation. The memory 630 may further store reliability catalogs [symbol] , tuples (K₀, K₁, . . . , K_{M-1}), learned model parameters θ for a deep Q-network, channel and SNR configurations, rate-matching patterns, and checkpoints/logs from training and simulation. In some embodiments, the rate-profiling module retrieves the stored catalog and allocation tuple from memory and uses them to generate the global information index set [symbol] . The auxiliary processor 623 (e.g., GPU) may accelerate batch decoding and RL updates, while the main processor 621 may apply data movement and decision logic.

The communication module 690 and antenna module 697 may provide an interface to transmit and receive codewords generated by the encoder pipeline, and to obtain over-the-air performance measurements that can be fed back into the design engine. During downlink reception, the communication module 690 may provide demodulated information (e.g., LLRs) to the processor 620 for execution of the steps shown in FIG. 3 (e.g., steps 301-307) to decode message bits; during uplink transmission, the processor 620 may generate codewords using the current global information index set [symbol] . Decoding outcomes and block-error-rate statistics may be aggregated and supplied to the rate-profile design engine to refine the allocation tuple (K₀, K₁, . . . , K_{M-1}). In some embodiments, the server 608 may store learned rate profiles; the interface 677 may import/export catalogs or tuples between the electronic device 601 and the server 608. The SIM card 696 may provide network credentials for device-to-server coordination, while the power management module 688 and battery 689 may support prolonged operation during iterative training or field evaluation.

These structures can provide technical improvements. Partitioning into components and representing designs by the tuple (K₀, K₁, . . . , K_{M-1}) may reduce the state and action dimensionality handled by the processor 620, thereby lowering computation and memory usage versus exhaustive search, and enabling faster convergence on the auxiliary processor 623. Storing reliability catalogs and learned parameters in the memory 630 may permit reproducible construction of [symbol] with low latency at run time, which can reduce decoding complexity and improve block-error-rate performance across varying list sizes, puncturing/shortening patterns, and channel conditions. Executing list-decoding (e.g., as per the steps shown in FIG. 3) using soft information from the communication module 690 may provide a consistent evaluation loop for profile selection. Offloading evaluation and learning to the auxiliary processor 623 or server 608 may further improve computational efficiency.

The input device 650 may receive a command or data to be used by another component (e.g., the processor 620) of the electronic device 601, from the outside (e.g., a user) of the electronic device 601. The input device 650 may include, for example, a microphone, a mouse, or a keyboard.

The sound output device 655 may output sound signals to the outside of the electronic device 601. The sound output device 655 may include, for example, a speaker or a receiver. The speaker may be used for general purposes, such as playing multimedia or recording, and the receiver may be used for receiving an incoming call. The receiver may be implemented as being separate from, or a part of, the speaker.

The display device 660 may visually provide information to the outside (e.g., a user) of the electronic device 601. The display device 660 may include, for example, a display, a hologram device, or a projector and control circuitry to control a corresponding one of the display, hologram device, and projector. The display device 660 may include touch circuitry adapted to detect a touch, or sensor circuitry (e.g., a pressure sensor) adapted to measure the intensity of force incurred by the touch.

The audio module 670 may convert a sound into an electrical signal and vice versa. The audio module 670 may obtain the sound via the input device 650 or output the sound via the sound output device 655 or a headphone of an external electronic device 602 directly (e.g., wired) or wirelessly coupled with the electronic device 601.

The sensor module 676 may detect an operational state (e.g., power or temperature) of the electronic device 601 or an environmental state (e.g., a state of a user) external to the electronic device 601, and then generate an electrical signal or data value corresponding to the detected state. The sensor module 676 may include, for example, a gesture sensor, a gyro sensor, an atmospheric pressure sensor, a magnetic sensor, an acceleration sensor, a grip sensor, a proximity sensor, a color sensor, an infrared (IR) sensor, a biometric sensor, a temperature sensor, a humidity sensor, or an illuminance sensor.

The interface 677 may support one or more specified protocols to be used for the electronic device 601 to be coupled with the external electronic device 602 directly (e.g., wired) or wirelessly. The interface 677 may include, for example, a high-definition multimedia interface (HDMI), a universal serial bus (USB) interface, a secure digital (SD) card interface, or an audio interface.

A connecting terminal 678 may include a connector via which the electronic device 601 may be physically connected with the external electronic device 602. The connecting terminal 678 may include, for example, an HDMI connector, a USB connector, an SD card connector, or an audio connector (e.g., a headphone connector).

The haptic module 679 may convert an electrical signal into a mechanical stimulus (e.g., a vibration or a movement) or an electrical stimulus which may be recognized by a user via tactile sensation or kinesthetic sensation. The haptic module 679 may include, for example, a motor, a piezoelectric element, or an electrical stimulator.

The camera module 680 may capture a still image or moving images. The camera module 680 may include one or more lenses, image sensors, image signal processors, or flashes. The power management module 688 may manage power supplied to the electronic device 601. The power management module 688 may be implemented as at least part of, for example, a power management integrated circuit (PMIC).

The battery 689 may supply power to at least one component of the electronic device 601. The battery 689 may include, for example, a primary cell which is not rechargeable, a secondary cell which is rechargeable, or a fuel cell.

The communication module 690 may support establishing a direct (e.g., wired) communication channel or a wireless communication channel between the electronic device 601 and the external electronic device (e.g., the electronic device 602, the electronic device 604, or the server 608) and performing communication via the established communication channel. The communication module 690 may include one or more communication processors that are operable independently from the processor 620 (e.g., the AP) and supports a direct (e.g., wired) communication or a wireless communication. The communication module 690 may include a wireless communication module 692 (e.g., a cellular communication module, a short-range wireless communication module, or a global navigation satellite system (GNSS) communication module) or a wired communication module 694 (e.g., a local area network (LAN) communication module or a power line communication (PLC) module). A corresponding one of these communication modules may communicate with the external electronic device via the first network 698 (e.g., a short-range communication network, such as BLUETOOTH™, wireless-fidelity (Wi-Fi) direct, or a standard of the Infrared Data Association (IrDA)) or the second network 699 (e.g., a long-range communication network, such as a cellular network, the Internet, or a computer network (e.g., LAN or wide area network (WAN)). These various types of communication modules may be implemented as a single component (e.g., a single IC), or may be implemented as multiple components (e.g., multiple ICs) that are separate from each other. The wireless communication module 692 may identify and authenticate the electronic device 601 in a communication network, such as the first network 698 or the second network 699, using subscriber information (e.g., international mobile subscriber identity (IMSI)) stored in the subscriber identification module 696.

The antenna module 697 may transmit or receive a signal or power to or from the outside (e.g., the external electronic device) of the electronic device 601. The antenna module 697 may include one or more antennas, and, therefrom, at least one antenna appropriate for a communication scheme used in the communication network, such as the first network 698 or the second network 699, may be selected, for example, by the communication module 690 (e.g., the wireless communication module 692). The signal or the power may then be transmitted or received between the communication module 690 and the external electronic device via the selected at least one antenna.

Commands or data may be transmitted or received between the electronic device 601 and the external electronic device 604 via the server 608 coupled with the second network 699. Each of the electronic devices 602 and 604 may be a device of a same type as, or a different type, from the electronic device 601. All or some of operations to be executed at the electronic device 601 may be executed at one or more of the external electronic devices 602, 604, or 608. For example, if the electronic device 601 should perform a function or a service automatically, or in response to a request from a user or another device, the electronic device 601, instead of, or in addition to, executing the function or the service, may request the one or more external electronic devices to perform at least part of the function or the service. The one or more external electronic devices receiving the request may perform the at least part of the function or the service requested, or an additional function or an additional service related to the request and transfer an outcome of the performing to the electronic device 601. The electronic device 601 may provide the outcome, with or without further processing of the outcome, as at least part of a reply to the request. To that end, a cloud computing, distributed computing, or client-server computing technology may be used, for example.

FIG. 7 is a system including a UE and a base station, in communication with each other, according to an embodiment.

Referring to FIG. 7, the UE may include a radio 715 and a processing circuit (or a means for processing) 720, which may perform various methods disclosed herein. For example, the processing circuit 720 may receive, via the radio 715, transmissions from a gNB (e.g., a BS, network node, satellite, or another electronic device) 710, and the processing circuit 720 may transmit, via the radio 715, signals to the gNB 710. In a downlink example, the radio 715 may provide information (e.g., LLRs) to the processing circuit 720, which may execute the list-decoding steps of FIG. 3 with a list size L to recover message bits; decoded outcomes and BLER statistics may be logged for use by a rate-profile design module. In an uplink example, the processing circuit 720 may implement the rate-profiling module, precoder module, and/or polar transform module of FIG. 2 to generate a codeword that the radio 715 may transmit to the gNB 710. The processing circuit 720 may further construct the global information index set A using the component-partitioning and catalog selection illustrated in FIG. 4 (e.g., mapping a tuple (K₀, K₁, . . . , K_{M-1}) to global indices).

Embodiments of the subject matter and the operations described in this specification may be implemented in digital electronic circuitry, or in computer software, firmware, or hardware, including the structures disclosed in this specification and their structural equivalents, or in combinations of one or more of them. Embodiments of the subject matter described in this specification may be implemented as one or more computer programs, i.e., one or more modules of computer-program instructions, encoded on computer-storage medium for execution by, or to control the operation of data-processing apparatus. Additionally or alternatively, the program instructions can be encoded on an artificially-generated propagated signal, e.g., a machine-generated electrical, optical, or electromagnetic signal, which is generated to encode information for transmission to suitable receiver apparatus for execution by a data processing apparatus. A computer-storage medium can be, or be included in, a computer-readable storage device, a computer-readable storage substrate, a random or serial-access memory array or device, or a combination thereof. Moreover, while a computer-storage medium is not a propagated signal, a computer-storage medium may be a source or destination of computer-program instructions encoded in an artificially-generated propagated signal. The computer-storage medium can also be, or be included in, one or more separate physical components or media (e.g., multiple CDs, disks, or other storage devices). Additionally, the operations described in this specification may be implemented as operations performed by a data-processing apparatus on data stored on one or more computer-readable storage devices or received from other sources.

While this specification may contain many specific implementation details, the implementation details should not be construed as limitations on the scope of any claimed subject matter, but rather be construed as descriptions of features specific to particular embodiments. Certain features that are described in this specification in the context of separate embodiments may also be implemented in combination in a single embodiment. Conversely, various features that are described in the context of a single embodiment may also be implemented in multiple embodiments separately or in any suitable subcombination. Moreover, although features may be described above as acting in certain combinations and even initially claimed as such, one or more features from a claimed combination may in some cases be excised from the combination, and the claimed combination may be directed to a subcombination or variation of a subcombination.

Similarly, while operations are depicted in the drawings in a particular order, this should not be understood as requiring that such operations be performed in the particular order shown or in sequential order, or that all illustrated operations be performed, to achieve desirable results. In certain circumstances, multitasking and parallel processing may be advantageous. Moreover, the separation of various system components in the embodiments described above should not be understood as requiring such separation in all embodiments, and it should be understood that the described program components and systems can generally be integrated together in a single software product or packaged into multiple software products.

Thus, particular embodiments of the subject matter have been described herein. Other embodiments are within the scope of the following claims. In some cases, the actions set forth in the claims may be performed in a different order and still achieve desirable results. Additionally, the processes depicted in the accompanying figures do not necessarily require the particular order shown, or sequential order, to achieve desirable results. In certain implementations, multitasking and parallel processing may be advantageous.

As will be recognized by those skilled in the art, the innovative concepts described herein may be modified and varied over a wide range of applications. Accordingly, the scope of claimed subject matter should not be limited to any of the specific exemplary teachings discussed above, but is instead defined by the following claims.

What is claimed is:

1. A computer-implemented method of defining a rate profile of a pre-coded polar code, comprising:
obtaining an allocation tuple that specifies, for at least one component included in a plurality of components, a count of information-bit positions equal to a message length;
for the at least one component, selecting, from a catalog, an information set of a component code corresponding to the count of information-bit positions;
generating a global information index set by concatenating the information set of the component code with an offset; and
transmitting, via an encoder, a codeword generated using a rate-profiling module configured based on the global information index set.

2. The method of claim 1, wherein the plurality of components are equal in size.

3. The method of claim 1, wherein the catalog associates, the count of information-bit positions with a reliability ordering of positions within the at least one component.

4. The method of claim 1, further comprising decoding the transmitted codeword using a list-based decoder.

5. The method of claim 1, wherein the catalog and the allocation tuple are stored in a memory, and the rate-profiling module retrieves the catalog and the allocation tuple from the memory to generate the global information index set.

6. The method of claim 1, wherein the allocation tuple specifies a number of information-bits assigned to each component included in the plurality of components.

7. The method of claim 1, wherein the offset is equal to an index of the at least one component multiplied by a component length.

8. A computer-implemented method for designing an information index set of a pre-coded polar code, comprising:
for a current allocation tuple, generating a global information index set by selecting, for a component included in a plurality of components, an information set from a catalog;
measuring a block-error rate for a code that uses the global information index set;
updating the allocation tuple by transferring one information position between components while preserving a total equal to a message length;
iterating at least one of the generating, measuring, or updating to select an allocation tuple having a lowest measured block-error rate within an episode; and
transmitting a codeword generated using a rate profiling module configured with the global information index set.

9. The method of claim 8, wherein the allocation tuple specifies, for each component, a count of information-bit positions that does not exceed that component's size and whose total equals the message length.

10. The method of claim 8, wherein the updating comprises selecting an ordered pair identifying a source component and a destination component, decrementing the source component's count by one and incrementing the destination component's count by one.

11. The method of claim 10, wherein a next allocation tuple is determined from the current allocation tuple and the ordered pair.

12. The method of claim 10, wherein the updating is implemented by an action-value function that receives the current allocation tuple, the action-value function being trained using stored transitions maintained in a replay buffer and updated using a target network.

13. The method of claim 8, further comprising computing, for each update, a reward equal to a difference in logarithms of a measured block-error rate between the current allocation tuple and a next allocation tuple.

14. The method of claim 13, wherein the iterating begins from a fixed initial allocation tuple, proceeds for a fixed number of moves, and selects the allocation tuple that maximizes an undiscounted sum of the reward.

15. A non-transitory computer-readable medium storing instructions that, when executed by one or more processors of an electronic device, cause the one or more processors to:
obtain an allocation tuple that specifies, for at least one component included in a plurality of components, a count of information-bit positions equal to a message length;
for the at least one component, select, from a catalog, an information set of a component code corresponding to the count of information-bit positions;
generate a global information index set by concatenating the information set of the component code with an offset; and
transmit, via an encoder, a codeword generated using a rate-profiling module configured based on the global information index set.

16. The non-transitory computer-readable medium of claim 15, wherein the plurality of components are equal in size.

17. The non-transitory computer-readable medium of claim 15, wherein the catalog associates the count of information-bit positions with a reliability ordering of positions within the at least one component.

18. The non-transitory computer-readable medium of claim 15, wherein the instructions further cause the one or more processors to decode the transmitted codeword using a list-based decoder.

19. The non-transitory computer-readable medium of claim 15, wherein the instructions further cause the one or more processors to store, in a memory, the catalog and the allocation tuple, and wherein the rate-profiling module is configured to retrieve the catalog and the allocation tuple from the memory to generate the global information index set.

20. The non-transitory computer-readable medium of claim 15, wherein the offset is equal to an index of the at least one component multiplied by a component length.
